(19) United States
(12) Patent Application Publication
(10) Pub. No.: US 2025/0217705 A1
(43) Pub. Date: Jul. 3, 2025

(54) METHOD FOR RADIATION SPECTRUM AWARE SOURCE MASK OPTIMIZATION FOR LITHOGRAPHY

(71) Applicants: ASML NETHERLANDS B.V., Veldhoven (NL); CYMER, LLC, San Diego, CA (US)

(72) Inventors: Willard Earl CONLEY, San Diego, CA (US); Michael Matthew CROUSE, Albany, NY (US); Christopher James KAPLAN, Oakland, CA (US); Tami Lynn COUNTS, San Jose, CA (US); Vincent Edward PLACHECKI, Chandler, AZ (US); Joshua Jon THORNES, San Diego, CA (US)

(21) Appl. No.: 18/876,525

(22) PCT Filed: Jul. 29, 2023
(86) PCT No.: PCT/EP2023/071100

§ 371 Date: Dec. 18, 2024

Related U.S. Application Data
(60) Provisional application No. 63/397,995, filed on Aug. 15, 2022.

(51) Int. Cl. G06N 20/00

(52) U.S. Cl. CPC G06N 20/00

(57) ABSTRACT

A method that including performance of source mask optimization (SMO) for a plurality of laser spectra. The method further includes generation of training data by determining, for each optimized source-mask-combination, performance metrics such as EPE, CDU, LER, LWR, DOF, NILS for the plurality of laser spectra and training of a machine learning (ML) model to determine an optimal laser spectrum based on the generated training data. The method may further including predicting optimal spectra for production design layouts using the trained ML model.

### CROSS-REFERENCE TO RELATED APPLICATIONS

This application claims priority of U.S. application 63/397,995 which was filed on Aug. 15, 2022 and which is incorporated herein in its entirety by reference.

### TECHNICAL FIELD

The description herein relates to a method and system for optimizing a spectrum for a radiation source for a lithographic process.

### BACKGROUND

A lithographic projection apparatus can be used, for example, in the manufacture of integrated circuits (ICs). A patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), and the reduction ratio can be different in x and y direction features the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

According to an embodiment, there is provided a method for acquiring, by a computer system, a plurality of design variables that represent at least one of characteristics of a lithographic process, geometrical characteristics of a design layout, or a combination thereof; and determining, by the computer system, a spectrum for a radiation source of a lithographic apparatus based on at least one of the plurality of design variables, the characteristics of the lithographic process, the geometrical characteristics of the design layout, or a combination thereof.

In an embodiment, the determining comprises determining, by the computer system, one or more parameters of the spectrum for the radiation source.

In an embodiment, the one or more parameters of the spectrum for the radiation source comprise at least one of a number of components, a wavelength separation between two or more components, a frequency separation between two or more components, a component shape, a component distribution, a component intensity, a relative intensity of two components, a component nominal focus, a component focus center, a component displacement, or a combination thereof.

In an embodiment, the determining comprises: determining, by the computer system, the spectrum for the radiation source based on a latitude of at least one of the plurality of design variables.

In an embodiment, the latitude comprises latitude for at least one of depth of focus, exposure, common process window, image contrast, image log slope (ILS), normalized image log slope (NILS), or a combination thereof.

In an embodiment, the determining comprises: determining, by the computer system, the spectrum for the radiation source based on a at least one lithographic metric.

In an embodiment, the at least one lithographic metric comprises at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), an image contrast, an image contrast latitude, a usable process window above a specific NILS threshold (nDOF), or a combination thereof.

In an embodiment, the determining comprises: determining, by the computer system, a spectrum for the radiation source from a plurality of spectra based on at least one of a lithographic metric, a design variable latitude, or a combination thereof, wherein the plurality of spectra comprise spectra for which at least one value of a lithographic metric, a design variable latitude, or a combination thereof has been pre-computed.

In an embodiment, the determining comprises: selecting, by the computer system, multiple spectra from the plurality of spectra; and determining a spectrum for the radiation source based on a combination of the multiple spectra.

In an embodiment, the determining comprises: determining, by the computer system, a spectrum for the radiation source based on a machine learning model trained to determine an optimal spectrum from at least one of the plurality of design variables, the characteristics of the lithographic process, the geometrical characteristics of the design layout, or a combination thereof.

In an embodiment, the machine learning model is trained to determine an optimal spectrum based on at least one lithographic metric.

In an embodiment, the machine learning model is further trained to generate an optimal spectrum based on a combination of multiple contributing components.

In an embodiment, the combination comprises a linear combination.

In an embodiment, the combination comprises a convolution of at least two of the multiple contributing components.

In an embodiment, the combination comprises an interpolation.

In an embodiment, at least one of the multiple contributing components is a Lorentzian.

In an embodiment, at least one of the multiple contributing components is a Gaussian.

In an embodiment, at least one of the multiple contributing components comprises a Voigt profile.

In an embodiment, the optimal spectrum is a freeform spectrum.

In an embodiment, the optimal spectrum has at least one of a smooth profile, a discontinuous profile, a non-differentiable profile, or a piece-wise combination thereof.

According to another embodiment, there is provided a method, comprising: acquiring a plurality of target patterns; acquiring a plurality of design variables that represent characteristics of lithographic processes for the plurality of target patterns; acquiring a plurality of spectra for a radiation source for the lithographic processes; determining lithographic metrics for the plurality of spectra for the plurality of target patterns based on the plurality of design variables that represent characteristics of the lithographic processes for the plurality of target patterns; and training a model, by using the lithographic metrics for the plurality of spectra, to determine one or more optimal spectra for a lithographic process based on an input target pattern, a set of design variables that represent characteristics of the lithographic process for the input target pattern, or a combination thereof.

In an embodiment, the model comprises a machine learning model.

In an embodiment, the machine learning model comprises a neural network.

In an embodiment, the machine learning model comprises a convolutional neural network.

In an embodiment, the model comprises a regression model.

In an embodiment, the model comprises an ensemble of machine learning models.

In an embodiment, the training comprises: training the model to determine an optimal spectrum.

In an embodiment, the training comprises: training the model to determine an optimal spectrum based on a combination of the one or more optimal spectra.

In an embodiment, the lithographic metrics comprises at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination thereof.

In an embodiment, the training of the model to determine one or more optimal spectra for the lithographic process comprises training the model to determine one or more optimal parameter of a spectrum for the lithographic process.

In an embodiment, the one or more optimal parameter comprises comprise at least one of a number of components, a wavelength separation between two or more components, a frequency separation between two or more components, a component shape, a component distribution, a component intensity, a relative intensity of two components, a component nominal focus, a component focus center, a component displacement, or a combination thereof.

In an embodiment, a method further comprising: acquiring a production target pattern, a set of design variables for that represent characteristics of the lithographic process for the production target pattern, of a combination thereof; and determining one or more optimal spectra for the lithographic process for the production target pattern based on the trained model.

In an embodiment, the training comprises training the model to determine one or more optimal spectra based on an input target pattern type.

In an embodiment, the training comprises training the model to determine an input target pattern type.

According to another embodiment, there is provided a method, comprising: computing, by a computer system, a multi-variable cost function of a plurality of design variables that represent characteristics of a lithographic process, the multi-variable cost function being a function of a spectrum of a radiation source of a lithographic apparatus, or being a function of a variable that is a function of the spectrum or that affects the spectrum; and reconfiguring, by the computer system, one or more of the characteristics of the lithographic process by adjusting one or more of the plurality of design variables until a termination criteria is satisfied.

According to another embodiment, there is provided a method comprising: computing, by a computer system, a multi-variable cost function being a function of a plurality of design variables that represent characteristics of a lithographic process; and reconfiguring, by the computer system, one or more of the characteristics of the lithographic process by adjusting one or more of the plurality of design variables and re-computing the multi-variable cost function based on the adjusted one or more of the plurality of design variables until a certain termination condition is satisfied, wherein a spectrum of a radiation source of a lithographic apparatus is adjustable during the reconfiguring.

In an embodiment, the reconfiguring is under a constraint that geometrical characteristics of a patterning device comprising a design layout of the lithographic process are substantially unchanged.

In an embodiment, the reconfiguring comprises adjusting the spectrum of the radiation source.

In an embodiment, the reconfiguring comprises selecting the spectrum of the radiation source from a plurality of spectra of the radiation source.

In an embodiment, the spectrum of the radiation source is comprised of multiple contributing components.

In an embodiment, the spectrum is comprised of a combination of contributing components.

In an embodiment, at least one of the multiple contributing components is a Lorentzian.

In an embodiment, at least one of the multiple contributing components is a Gaussian.

In an embodiment, at least one of the multiple contributing components comprise a Voigt profile.

In an embodiment, the spectrum of the radiation source has at least one of a smooth profile, a discontinuous profile, a non-differentiable profile, or a piece-wise combination thereof.

In an embodiment, the reconfiguring improves an image quality characteristic of the lithographic process.

In an embodiment, the reconfiguring increases a latitude of at least one of the plurality of design variables.

In an embodiment, the latitude comprises a latitude for at least one of depth of focus, exposure, common process window, image contrast, image log slope (ILS), normalized image log slope (NILS), or a combination thereof.

In an embodiment, the multi-variable cost function evaluates at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination thereof.

In an embodiment, the reconfiguring comprises an optimization of the multi-variable cost function.

In an embodiment, the reconfiguring comprises a gradient-based optimization.

According to another embodiment, there is provided one or more non-transitory, machine-readable medium having instructions thereon, the instructions when executed by a processor being configured to perform the method of any one of another embodiment.

According to another embodiment, there is provided a system comprising: a processor; and one or more non-transitory, machine-readable medium having instructions thereon, the instructions when executed by the processor being configured to perform the method of any one of another embodiment.

According to another embodiment, there is provided a system comprising: a processor; a laser; and one or more non-transitory, machine-readable medium having instructions thereon, the instructions when executed by the processor being configured to perform the method of any one of another embodiment.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3. is a schematic overview of spectrum-aware optimization for a lithography process, according to an embodiment.

FIG. 4 illustrates an exemplary method spectrum-aware optimization for a lithography process, according to an embodiment.

FIG. 5 illustrates example spectra for spectrum-aware optimization for a lithography process, according to an embodiment.

FIG. 6 is a schematic overview of generating training data for spectrum-aware optimization for a lithography process, according to an embodiment.

FIG. 7 illustrates an exemplary method for training a model for spectrum-aware optimization, according to an embodiment.

FIG. 8 is a schematic overview of spectrum-aware optimization for a lithography process based on a trained model, according to an embodiment.

FIG. 9A illustrates an exemplary method for spectrum adjustment using a model during spectrum-aware optimization for a lithography process, according to an embodiment.

FIG. 9B illustrates an exemplary method for spectrum determination using a model during spectrum-aware optimization for a lithography process, according to an embodiment.

FIG. 10 is a schematic overview of spectrum-aware optimization with pattern classification, according to an embodiment.

FIG. 11A depicts example spectra for spectrum-aware optimization for an example lithography process, according to an embodiment.

FIG. 11B depicts graphs showing process window improvement due to spectrum-aware optimization for the example lithography process of FIG. 11A, according to an embodiment.

FIG. 12 depicts example spectra determined by spectrum-aware optimization for an example lithography process, according to an embodiment.

FIG. 13 is a block diagram of an example computer system, according to an embodiment.

FIG. 14 is a schematic diagram of a lithographic projection apparatus, according to an embodiment.

FIG. 15 is a schematic diagram of another lithographic projection apparatus, according to an embodiment.

FIG. 16 is a detailed view of the lithographic projection apparatus, according to an embodiment.

FIG. 17 is a detailed view of the source collector module of the lithographic projection apparatus, according to an embodiment.

### DETAILED DESCRIPTION

The present disclosure describes source mask optimization which includes determination of a radiation spectrum for a radiation source for a lithography process. The determination of the radiation spectrum can include determination of an optimal spectrum (e.g., optimization of a radiation spectrum). The radiation spectrum can be determined based on multiple spectra, based on a model, including a machine learning model, selected from a library, interpolated, etc. The radiation spectrum can be a freeform spectrum generated from one or more constituted components. The determination of the radiation spectrum can be part of a source-mask optimization for a lithography process. The determination of the radiation spectrum can be iterative. The radiation spectrum can be determined based on a cost function.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm). In the present document, the term “radiation source” or “source” is used to encompass all types of sources of radiation, including laser sources, incandescent sources, etc. which may include treatment of the radiation between the radiation source and the target or other parts of the optics, including filtering, collimating, focusing, etc. A source may include multiple sources which generate contributions to the radiation used for lithography, including sources which combine multiple contributions from one or more sources, where contributions may have been altered with respect to one another, including by filtering, wavelength shifting, etc. Contributions to the radiation of the source may include excitation responses from an element, compound, mixture, etc. and contributions may be combined in one or more ways, such as additively, subtractively, convolutionally, etc.

A patterning device can comprise, or can form, one or more design layouts. The design layout may be generated utilizing CAD (computer-aided design) programs, including general CAD programs such as AutoCAD, Solidworks, etc., or which may be layout specific CAD programs such as LayoutEditor, KLayout, etc. This process is often referred to as EDA (electronic design automation). Most CAD programs follow a set of predetermined design rules in order to create functional design layouts/patterning devices. These rules are set based processing and design limitations. For example, design rules define the space tolerance between devices (such as gates, capacitors, etc.) or interconnect lines, to ensure that the devices or lines do not interact with one another in an undesirable way. One or more of the design rule limitations may be referred to as a “critical dimension” (CD). A critical dimension of a device can be defined as the smallest width of a line or hole, or the smallest space between two lines or two holes. Thus, the CD regulates the overall size and density of the designed device. One of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective; binary, phase-shifting, hybrid, etc.), examples of other such patterning devices include a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. Examples of other such patterning devices also include a programmable LCD array. An example of such a construction is given in U.S. Pat. No. 5,229,872, which is incorporated herein by reference.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device.

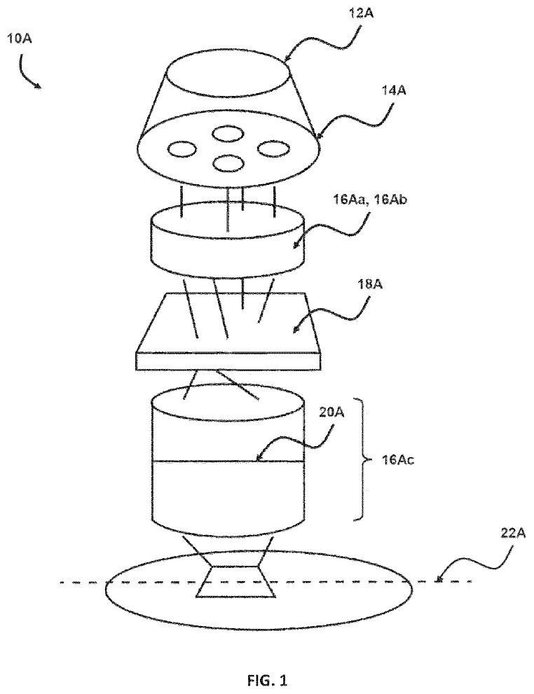

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (the lithographic projection apparatus itself need not have the radiation source), illumination optics which, e.g., define the partial coherence (denoted as sigma) and which may include optics 14A, 16Aa and 16Ab that shape radiation from the source 12A; a patterning device (or mask) 18A; and transmission optics 16Ac that project an image of the patterning device pattern onto a substrate plane 22A.

According to an embodiment of the present disclosure, the radiation source may include systems for providing and altering a spectrum of the radiation provided by the radiation source. Altering the spectrum can include adding or subtracting components of the spectrum, including composing a spectrum of multiple components, altering a distribution of wavelengths for a contributing component (for example from Gaussian to Lorentzian), changing a dispersion of a component, or otherwise changing intensity of the radiation source for a wavelength.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. In some instances, the source may provide patterning, directing, or shaping to the radiation. In some instances, patterning, directing, or shaping of radiation may occur between the source and the projection optics. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

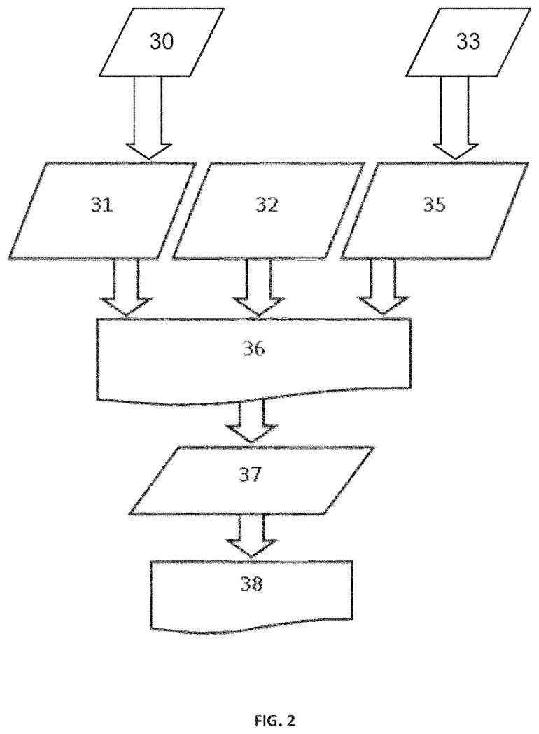

FIG. 2 illustrates an exemplary flow chart for simulating lithography in a lithographic projection apparatus, according to an embodiment. Source model 31 represents optical characteristics (including radiation intensity distribution and/or phase distribution) of the source. Spectrum model 30 represents components of the spectrum (including number of components, shape of components, intensity as a function of wavelength, peak width, etc.). Spectrum model 30 can be a part of or distinct from the source model 31. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, source model 31 can represent the optical characteristics of the source that include, but are not limited to, numerical aperture settings, illumination sigma (a) settings as well as any particular illumination shape (e.g., off-axis radiation sources such as annular, quadrupole, dipole, etc.). Spectrum model 30 can represent spectral characteristics of the source that include, but are not limited to, number of spectral components, shape of spectral components (e.g., Gaussian, Lorentzian, boxcar, etc.), shape of spectrum (e.g., intensity as a function of wavelength), qualities of spectrum (e.g., smooth, continuous, discontinuous, differentiable, non-differentiable, etc.), and other spectrum quantities and qualities. Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or another file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e., circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$C F ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( 1 )$$

where (z₁, z₂, . . . , z_{N}) are N design variables or values thereof. fₚ (z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF (z₁, z₂, z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ (z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a resist model (e.g., that models physical effects of the resist, such as chemical effects due to the light), an optical proximity correction (OPC) model (e.g., that can be used to make masks or reticles and may include sub-resolution assist features (SRAFs), etc.).

As used herein, the term “concurrently” means that two or more things are occurring at approximately, but not necessarily exactly, at the same time. For example, varying a pupil design concurrently with a mask pattern can mean making a small modification to a pupil design, then making a small adjustment to a mask pattern, and then another modification to the pupil design, and so on. However, the present disclosure contemplates that in some parallel processing applications, concurrency can refer to operations occurring at the same time, or having some overlapping in time.

The present disclosure provides apparatuses, methods and computer program products which, among other things, relate to modifying or optimizing features of a lithography apparatus in order to increase performance and manufacturing efficiency. The features that can be modified can include an optical spectrum of light used in the lithography process, a mask, a pupil, etc. Any combination of these features (and possibly others) can be implemented in order to improve, for example, a depth of focus, a process window, a contrast, or the like, of a lithography apparatus. In some embodiments, modification of one feature affects the other features. In this way, to achieve the desired improvements, multiple features can be concurrently modified/varied, as described below.

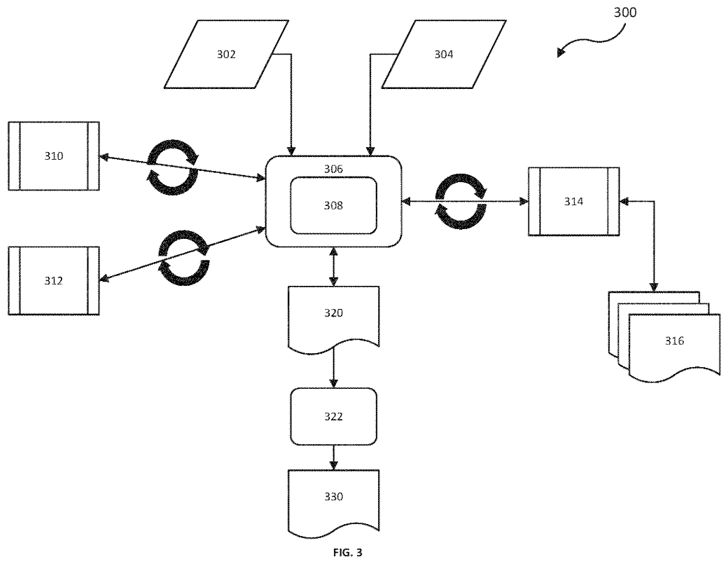

FIG. 3 depicts a schematic overview of stochastic-aware optimization for a lithography process 300. The lithography process 300 may be any type of lithography process, including UV, EUV, etc. The lithography process may be characterized by a design layout 302 and a set of requirements 304. The design layout 302 may include information about multiple layers. The design layout 302 may include information about three-dimensional shapes of features contained in the design layout 302. The set of requirements 304 may be instrumentation requirements (e.g., limitations, ranges, etc. corresponding to process equipment), material requirements (e.g., limitations, ranges, etc. imposed on a lithography process by materials of the device to be fabricated which may or may not be exposed or patterned by the current lithography process), customer requirements (e.g., limitations, ranges, etc. requested by the supplier of the design layout 302), etc. The set of requirements 304 may include a set of design rules, with which a recipe 330 for the lithography process may preferentially comply.

A process optimizer 306 may operate to optimize the lithography process 300. The design layout 302 and set of requirements 304 may be input into the process optimizer 306 or acquired by the process optimizer 306. The process optimizer 306 may optimize the recipe 330 for the lithography process 300 in order to comply with the design layout 302 and the set of requirements 304. The process optimizer 306 may also optimize process window conditions, including exposure latitude, common process window, etc., or other lithography metrics, including EPE, LCDU, etc., which may be extraneous to the design layout 302 or the set of requirements 304. The process optimizer 306 may operate based on a cost function 308.

The cost function 308 can include weighted contributions from lithography metrics, such as EPE. The cost function 308 can also include penalties for various parameters, which can be used to drive the process optimizer 306 towards a recipe 330 which satisfies the design layout 302 and the set of requirements 304. The cost function 308 can be a multi-variable cost function. The cost function 308 may be a differentiable function. The cost function 308 can be used by the process optimizer 306 to optimize a recipe 330, such as by gradient descent or other methods. The cost function 308 can be determined based on an iteration of a lithography recipe, where the recipe 330 is the optimized iteration of the lithography recipe. Optimization includes determination of a recipe, source configuration, mask configuration, etc. which satisfies the design layout 302 and the set of requirements 304. Optimization is not limited to determination of the best of all possible recipes or configurations, but includes determination of recipes or configurations which fall within an allowable threshold of an ideal recipe or configuration or which otherwise satisfy the design layout 302 and the set of requirements 304. Optimization may include choosing between multiple recipes or configurations which satisfy the design layout 302 and the set of requirements 304, including choosing based on process window considerations, lithographic metric considerations, etc.

The cost function 308 can be determined based on a mask configuration, which may be determined based on a mask optimization 310. The mask optimization 310 can operate iteratively on a mask configuration, including by making changes to the mask configuration based on the cost function 308. The mask optimization 310 can include a continuous transmission mask (CTM) optimization, a polygon optimization, a Manhattanized optimization, etc. The mask optimization 310 can include generation of one or more assist features. The mask optimization 310 can interact with a lithography model, such as a resist model, a photon model, an etch model, etc. which can be used to generate a predicted output of the lithography process 300 for an iteration of the mask optimization 310.

The cost function 308 can be determined based on a source configuration, which may be determined based on a source optimization 312. The source optimization can operate iteratively on a source configuration, including by making changes to the mask configuration based on the cost function 308. The source optimization 312 can include an unconstrained freeform optimization, a freeform optimization, etc. The source optimization 312 can include optimization of one or more parameters of a source configuration. The source optimization 312 can interact with a lithography model, such as a resist model, a photon model, an etch model, etc. which can be used to generate a predicted output of the lithography process 300 for an iteration of the source optimization 312.

The cost function 308 can be determined based on a radiation spectrum, which may be determined based on a spectrum optimization 314. The spectrum optimization 314 can operate iteratively on a radiation spectrum, including by adding or subtracting a component to the spectrum, changing a shape of a component of a spectrum, etc. The spectrum optimization 314 can include optimization of one or more parameters of a radiation source. The spectrum optimization 314 can interact with a lithography model, such as a resist model, a photon model, an etch model, etc. which can be used to generate a predicted output of the lithography process 300 for an iteration of the spectrum optimization 314.

The spectrum optimization 314 can operate based on a spectrum library 316. The spectrum library 316 can contain spectra for the lithography process 300 for which various parameters have been determined. The spectra can comprise one or more contribution, e.g., peak, with a central wavelength, wavelength dispersion, distribution shape, etc. The spectra can comprise laser line spectra, which can be combined to generate additional spectra. The spectrum library 316 can contain lithography parameters associated with the spectra, such as one or more performance indicator, which can be used to determine one or more optimal spectra of the multiple spectra. The spectrum optimization 314 can additionally or alternatively operate on combination of spectra of the spectrum library 316, freeform spectra, and/or generate new spectra not contained within the spectrum library 316.

The process optimizer 306 can also interact with other optimization processes, including dose optimization, focus optimization, spectrum optimization, etc. The mask optimization 310, the source optimization 312, and the spectrum optimization 314 can occur simultaneously, alternatively, on different time scales, etc. The process optimizer 306 operate to co-optimize the mask optimization 310, the source optimization 312, and the spectrum optimization 314. The process optimizer 306 can operate to co-optimize the mask optimization 310 and the source optimization 312, and then optimize the spectrum optimization 314 based on the co-optimization of the mask optimization 310 and the source optimization 312. The spectrum optimization 314 may operate based on selection of a performance indicator instead of optimization of the cost function 308.

The process optimizer 306 may determine the cost function 308 based on a current iteration of the recipe of the lithography process 300. The process optimizer 306 may determine the cost function 308 based on a modeled output of the current iteration of the lithography process 300. The process optimizer 306 may determine a recipe 330 that satisfies the design layout 302 and set of requirements 304 for the lithography process 300. The recipe 330 may be an optimized recipe, where optimized does not require that the recipe be the best recipe but rather refers to a recipe that at least satisfies a set of conditions-such as the design layout 302, the set of requirements 304, etc.

The process optimizer 306 may determine process window conditions 320 for a current iteration of the lithography process 300. The process window conditions 320 may or may not include variables which are used to determine the cost function 308. For example, an exposure latitude may be included in the process window conditions 320, but may or may not be a variable upon which the cost function 308 depends. In another example, edge placement error (EPE) may be used to determine the cost function 308, but may not be a process window condition 320. The process window conditions 320 may include one or more latitude, such as an exposure latitude, a dose latitude, etc. The process window conditions 320 may include a measurement (e.g., a range) of values of one or more parameter for which the current iteration of the lithography process 300 satisfies the design layout 302 and the set of requirements 304. The process window conditions 320 may be measured as a function of the current iteration of the lithography process 300. Alternatively, one or more of the process window conditions 320 can be optimized for by the process optimizer 306, using the cost function 308 or another process.

The process window conditions 320 of an output of the process optimizer 306 for the current iteration of the lithography process 300 can be checked by a lithography manufacturability check 322, which can check the current iteration of the lithography process 300 against lithography manufacturability guidelines. For example, the lithography manufacturability check 322 may determine that a current iteration of the lithography process 300 includes a source configuration that is incompatible with a radiation source of the lithography process 300. The lithography manufacturability check 322 may be performed on every configuration or iteration, or may be performed in part on most configurations or iterations, and may also include a final iteration of the lithography manufacturability check 322 before outputting the recipe 330 for the lithography process 300. The lithography manufacturability check 322 may also determine if the source configuration, mask configuration, and spectrum are compatible in combination for the lithography process 300.

The recipe 330 may be output to one or more lithography equipment. For example, the recipe 330 may be output in full or in part to a mask writer, a source configurer, a laser (which may provide at least part of the spectrum), etc. The recipe 330 may also be stored in one or more memory storage.

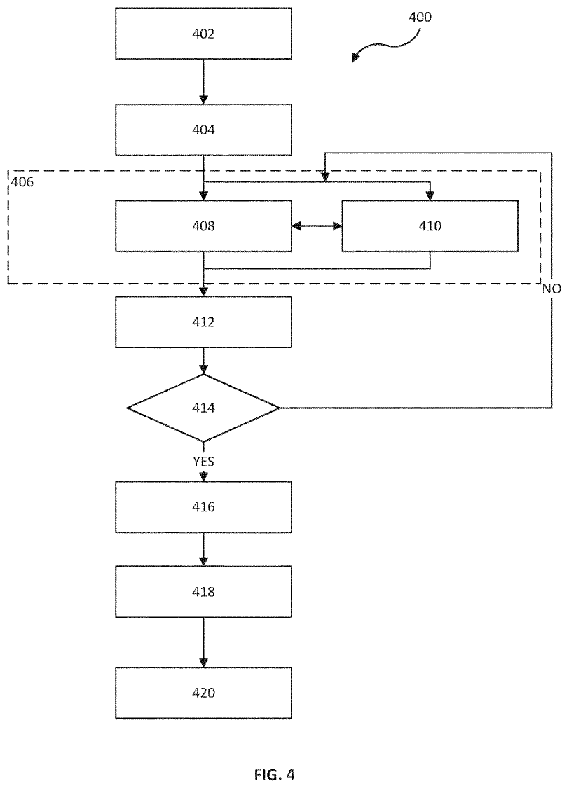

FIG. 4 illustrates an exemplary method 400 for spectrum-aware optimization for a lithography process. The operations of method 400 presented below are intended to be illustrative. In some embodiments, method 400 may be accomplished with one or more additional operations not described, and/or without one or more of the operations discussed. Additionally, the order in which the operations of method 400 are illustrated in FIG. 4 and described below is not intended to be limiting. In some embodiments, one or more portions of method 400 may be implemented (e.g., by simulation, modeling, etc.) in one or more processing devices (e.g., one or more processors). The one or more processing devices may include one or more devices executing some or all of the operations of method 400 in response to instructions stored electronically on an electronic storage medium. The one or more processing devices may include one or more devices configured through hardware, firmware, and/or software to be specifically designed for execution of one or more of the operations of method 400, for example.

At an operation 402, a layout is obtained for a lithography process. The layout can be a design layout (e.g., a pre-OPC design layout) which can be provided in a standardized digital file format such as GDSII or OASIS or another file format. The layout can be a layout of a single layer or a multi-layer layout. The layout may correspond to a single lithography process, a multi-step lithography process, multiple lithography processes, etc. The layout can comprise a set of desired features and may include information on tolerances, such as acceptable edge placement errors, CD, etc.

At an operation 404, requirements are obtained for the lithography process. The requirements can be instrument requirements, material requirements, process requirements, design requirements, etc. which define allowable ranges or values for various parameters of the lithography process. The requirements may correspond to a single lithography process, a multi-step lithography process, multiple lithography processes, etc. The requirements may bound or restrict one or more variables of the lithography process which can be optimized. The operation 404 and the operation 402 can be performed concurrently, sequentially in either order, synchronously, asynchronously, etc.

At an operation 406, at least one of a source optimization, mask optimization, or a combination thereof is performed for the lithography process. The operation 406 can be performed based on a cost function, which may be determined based on one or more models of the lithographic process, including an optical model, an etch model, a photon shot model, a resist chemistry model, etc. The operation 406 can comprise an iterative process based on iterations of a recipe for the lithography process. The operation 406 can comprise modeling the outcome of a current iteration of the recipe for the lithography process and determining a value of a cost function based on the modeled outcome. The operation 406 can include optimization based on the cost function, such as through gradient descent or other appropriate methods. The cost function can be a multi-variable cost function, which can depend on design variables, including source parameters, mask parameters, etc. The cost function can also include penalty terms, which can be a function of design variables, a function of modeled parameters, etc., (e.g., side lobe penalties, process window penalties) which may reduce undesired source and mask configurations, accelerate convergence towards stable configurations, and increase process robustness. The cost function can depend on one or more lithographic metric, including modeled lithographic metrics, which can include edge placement error (EPE), critical dimension (CD), critical dimension uniformity (CDU), local critical dimension uniformity (LCDU), line edge roughness (LER), line width roughness (LWR), resist contour characteristic, maximum defect size, exposure latitude, image shift, mask error enhancement factor, focus, depth of focus (DOF), DOF latitude, critical dimension depth of focus, process window latitude, common process window latitude, exposure latitude, image log slope (ILS), normalized image log-slope (NILS), image contrast, image contrast latitude, usable process window above a specific NILS threshold (nDOF), etc.

The operation 406 can continue until a termination criterion is satisfied. The termination criteria can be a number of iterations, a value of the cost function, a threshold of agreement between modeled parameters based on the current iteration of the optimization and the design layout, etc. The operation 406 can output a recipe based on the optimization of the lithography process for an iteration that satisfies the termination criterion.

The operation 406 can comprise an operation 408, an operation 410, or a combination thereof. The operation 408 and the operation 410 can be performed concurrently, sequentially in either order, in series, in parallel, synchronously, asynchronously, etc. The operation 408 and the operation 410 can be performed based on the same cost function. The operation 408 and the operation 410 can have the same termination criterion.

At the operation 408, a source optimization is performed for the lithography process. The source optimization may optimize parameters of the source. Source optimization may include optimization of optical characteristics of the source, including aperture settings, illumination settings, illumination shape, etc. The source optimization may be performed based on a cost function, where the cost function may be a function of one or more design variable corresponding to the source.

At the operation 410, a mask optimization is performed for the lithography process. The mask optimization may optimize parameters of the mask. Mask optimization may include optimization of clips, optimization of mask layout, optimization of SRAFs, optimization of physical characteristics of a mask design, etc. The mask optimization may be performed based on a cost function, where the cost function may be a function of one or more design variables corresponding to the mask.

At an operation 412, a process window is determined for the recipe of the lithography process. The recipe may include the source optimization, the mask optimization, or the combination thereof for which the termination criterion is satisfied. The process window can be a measure of a range of values for one or more design parameters for which a recipe satisfies the layout and requirements of the lithography process. The process window conditions can include latitudes for depth of focus, exposure, image contrast, image log slope (ILS), normalized image log slope (NILS), etc. The process window can include process windows for one or more processes of the lithography process. The process window can be or include a common process window. The process window can be determined based on one or more model for the lithography process.

At an operation 414, it is determined if the recipe for the lithography process corresponds to acceptable parameters. The parameters may be process window parameters, lithography metrics, source parameters, mask parameters, etc. The parameters may include a termination criterion. If the recipe corresponds to acceptable parameters, flow continues to an operation 416. If it is not determined that the recipe corresponds to acceptable parameters, flow continues to the operation

At an operation 416, a source spectrum is determined. The source spectrum may be determined based on the recipe. The source spectrum may be determined based on the source optimization, the mask optimization, or the combination thereof. The source spectrum may be selected from a library of spectra. The source spectrum may be selected from a library of components and composed of one or more components of spectra. The source spectrum may be determined based on a machine learning model. The lithography process may be classified, for example by a machine learning model, and the source spectrum may be determined based on the classification. The source spectrum may be selected based on one or more performance indicator. The source spectrum may be

At an operation 418, the recipe is checked for lithography compatibility. The recipe may be checked by a lithographic manufacturing checker (LMC), which may determine if the recipe produces incompatible processes. The LMC may determine if one or more portions of the recipe are incompatible with each other or likely to generate unacceptable levels of defects. The LMC may determine defect density, defect variation, hotspot variability, etc. The LMC may be used to determine if the recipe meets a reliability threshold. If the recipe is not compatible, the operation 406 may be performed again on an adjusted layout and/or requirements. Additionally or instead, weights of the cost function may be adjusted, which may include use of additional penalty terms, to reduce defect dense areas for a recipe.

At an operation 420, the recipe is output. The recipe may be output to one or more lithography tool, such as a photolithography tool, a mask aligner, a scanner, etc. The recipe may be output to a radiation source, which may include one or more radiation sources which can produce the spectrum. The recipe may additionally or instead be output to storage. The recipe may be output to more than one device (e.g., tool), saved in more than one piece, or a combination of both saved and output to devices. The recipe may be checked for compatibility with tools for which a part of the recipe is intended. If the recipe is incompatible with a tool, a different tool may be selected for the recipe and/or the recipe may be re-optimized with an updated set of requirements which include additional tool limitations.

As described above, method 400 (and/or the other methods and systems described herein) is configured to perform spectrum-aware optimization for a lithography process.

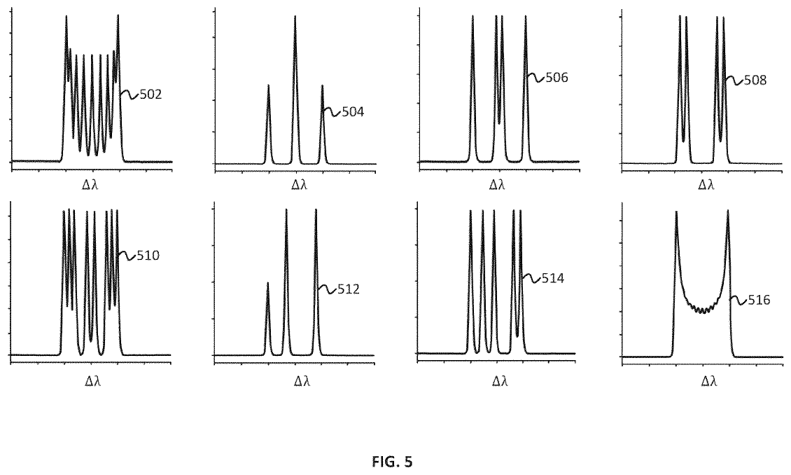

FIG. 5 illustrates example spectra for spectrum-aware optimization for a lithography process. FIG. 5 contains several example spectra, spectrums 502, 504, 506, 508, 510, 512, 514, and 516, which may be selected for a lithography process based on spectrum-aware optimization. The spectrums 502, 504, 506, 508, 510, 512, 514, and 516 are plotted in intensity in arbitrary units along a y-axis as a function of wavelength along an x-axis. The spectrums 502, 504, 506, 508, 510, 512, 514, and 516 are comprised of multiple peaks, each representing an individual contribution to the spectra. The spectrums 502, 504, 506, 508, 510, 512, 514, and 516 as depicted comprise combinations of various components, which can be Gaussian, Lorentzian, Voigt, etc. distributions of wavelengths. The spectrums 502, 504, 506, 508, 510, 512, 514, and 516 can be linear combinations of various components, with separations and relative intensities determined by spectrum-aware optimization. The spectrums 502, 504, 506, 508, 510, 512, 514, and 516 can also comprise convolutions of various components. The components of the spectrums 502, 504, 506, 508, 510, 512, 514, and 516 can also have different shapes, dispersion relationships, side peaks, and/or other effects added to the components themselves of the combination of components. The spectrums 502, 504, 506, 508, 510, 512, 514, and 516 are provided as non-limiting, illustrative examples and do not illustrate all the available spectra or components.

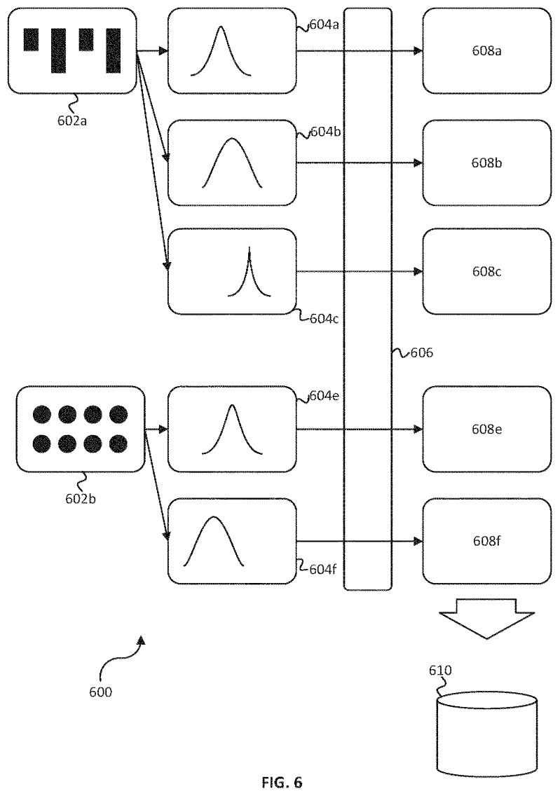

FIG. 6 is a schematic overview 600 of generating training data for spectrum-aware optimization for a lithography process. Generating training data, or a library of spectra which may include performance metrics, may comprise determining a pattern classification based on a design layout and/or a set of design requirements. A lithography process may be classified by a type of pattern. The pattern type may correspond to the size and/or shape of the features of the design. For example, the pattern may be classified as a linear pattern (e.g., a pattern comprising lines or other rectilinear shapes) or a circular pattern (e.g., a pattern comprising contact holes or other curved shapes). The pattern type may be classified as a pitch (e.g., a regularly repeating pattern) or a non-repeating pattern. The pattern type may be classified by which type of feature the pattern corresponds to, for example a memory feature, a via feature, etc. The pattern type may be classified in multiple ways.

Training data 610 may be generated based on pattern types, which can be grouped by one or more pattern classification. Training data 610 may also be generated based on selected pattern. In a non-limiting illustrative example, a linear pattern 602a and a circular pattern 602b are used to generate training data. For each pattern of the training set, one or more spectra are selected. In the non-limiting illustrative example, spectra 604a, 604b, and 604c are selected for the linear pattern 602a, while spectra 604e and 604f are selected for the circular pattern 602b. The same spectra or different spectra in the same or different number may be selected for each pattern. The spectra may comprise components, such as individual intensity peaks corresponding to optical excitations. The spectra may comprise multiple constituent components, such as depicted in the spectrums 502-516 of FIG. 5. The spectra may comprise components with different shapes or distributions, such as Gaussian, Lorentzian, Voigt, etc.

For each spectra selected for a pattern of the training set, a source-mask optimization 606 can be performed. The source-mask optimization 606 can be determined based on the design layout and set of requirements of the pattern. The source-mask optimization 606 can produce a recipe for the lithography process corresponding to the design layout and set of requirements for the pattern of the training set. A set of performance metrics can be determined for the recipe generated by the source-mask optimization 606. Each spectrum can be related to a set of performance metrics 608a-608f determined for the lithography process as optimized. In the non-limiting, illustrative example, the spectrum 604a can correspond to performance metrics 608a, the spectrum 604b can correspond to performance metrics 608b, the spectrum 604c can correspond to performance metrics 608c, the spectrum 604e can correspond to performance metrics 608e, the spectrum 604f can correspond to performance metrics 608f. The performance metrics can include lithography metrics—including EPE, CD, LCDU, etc. as previously described. The performance metrics can also or instead include process window conditions—including exposure latitude, DOF latitude, etc. as previously described. The performance metrics can include multiple parameters which describe one or more part of the lithography process or output of the lithography process. The performance metrics can include indication of an optimal spectrum for a pattern. An optimal spectrum may be the spectrum with the best lithographic metrics (e.g., smallest EPE, smallest CD, lowest predicted defect rate, etc.) or best process window conditions (e.g., largest latitudes) of the spectra selected for inclusion in the training data. Selection of an optimal spectrum is not limited to selection of the absolute optimal spectrum of infinite available spectra, but rather selection of a spectrum which is best based on a specific metric out of a set of available spectra or spectra generation in which resources are finite.

The training data 610 can then be generated based on the performance metrics associated with the spectra corresponding to each of the patterns including in the training set. The training data 610 can comprise pattern and spectra pairs which are labeled with values of one or more performance metric. The training data 610 may also include a recipe for the lithography process generated by the source-mask optimization. The training data 610 may include a classification of a pattern into one or more pattern type. The training data 610 may also be divided into training data sets which correspond to one or more pattern type, such as can be used to train multiple machine learning models or ensembles of machine learning models. The training data 610 may be used to train a model other than a machine learning model. The training data 610 may further or instead comprise a spectral library, in which spectra are associated with performance metrics. A spectral library may be used to select spectra based on desired performance metrics.

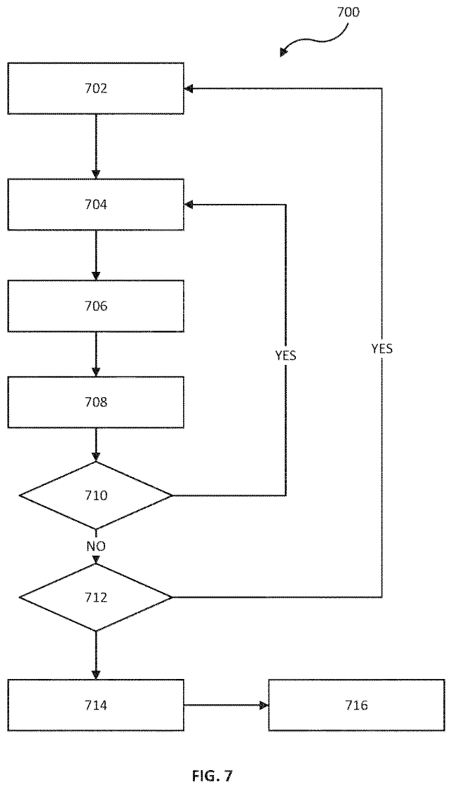

FIG. 7 illustrates an exemplary method 700 for training a model for spectrum-aware optimization. The operations of method 700 presented below are intended to be illustrative. In some embodiments, method 700 may be accomplished with one or more additional operations not described, and/or without one or more of the operations discussed. Additionally, the order in which the operations of method 700 are illustrated in FIG. 7 and described below is not intended to be limiting. In some embodiments, one or more portions of method 700 may be implemented (e.g., by simulation, modeling, etc.) in one or more processing devices (e.g., one or more processors). The one or more processing devices may include one or more devices executing some or all of the operations of method 700 in response to instructions stored electronically on an electronic storage medium. The one or more processing devices may include one or more devices configured through hardware, firmware, and/or software to be specifically designed for execution of one or more of the operations of method 700, for example.

At an operation 702, a layout and requirements are obtained for a lithography process. The layout can be obtained in any appropriate manner, such as those described in relation to the operation 402 of FIG. 4. The requirements can be obtained in any appropriate manner, such as those described in relation to the operation 404 of FIG. 4. Obtaining of the layout and obtaining of the requirements can be performed concurrently, sequentially in either order, synchronously, asynchronously, etc.

At an operation 704, a spectrum is selected for a radiation source of the lithography process. The spectrum can be selected from a set of spectrums, generated from a priori from a set of spectra guidelines, generated from one or more other spectrums (for example, through a convolution, linear combination, etc.), etc. The spectrum can be selected based on a set of allowable guidelines, which can correspond to a laser or other radiation source. The spectrum can be selected based on previously identified spectra for a lithography source—e.g., the spectrum can be generated by adjusting one or more parameters of a previously identified spectrum for a lithography process. The spectrum can be generated without regards to allowable spectra for a radiation source. For example, the spectrum may be a theoretical spectrum which may not be producible by a specific radiation source. A radiation source may be adjusted based on an identified spectrum or multiple radiation sources may be combined, so previously unallowable spectra may be selected for model training.

The selected spectrum may be parameterized. The selected spectrum may be described as a spectrum (e.g., in the form of intensity as a function of wavelength). The selected spectrum may be described as a set of parameters, such as a number of components, wavelength separation distance of such components, intensity of such components, etc. The selected spectrum may be symmetrical about a central wavelength or may be asymmetrical. The selected spectrum may be described by one or more full width half max (FWHM) for one or more component. The selected spectrum may be described by one or more distribution type for one or more component.

At an operation 706, a source-mask optimization (SMO) is performed for the lithography process. The SMO can be performed based on the layout and requirements obtained for the lithography process. The SMO can adjust various parameters of the source, the mask, and a combination thereof in order to provide an optimized recipe for the lithography process. The SMO can operate based on the selected spectrum, where the selected spectrum may not be adjusted during the SMO. Alternatively, adjustments to the spectrum may be made based on the source optimization, requirements for the lithography process, etc. The SMO can be previously performed, such as for a previously modeled and/or fabricated lithography process, which can be included in training data. The SMO can be performed in batches, for one or more layout and requirements. The SMO may be performed individually for a spectrum or may be performed in part or in full for a set of spectra.

The operation 706 can be performed based on a cost function, such as previously described in reference to the operation 406 of FIG. 4. The operation 706 can be performed based on a cost function, which may be determined based on one or more models of the lithographic process, including an optical model, an etch model, a photon shot model, a resist chemistry model, etc. The operation 706 can comprise an iterative process based on iterations of a recipe for the lithography process. The operation 706 can comprise modeling the outcome of a current iteration of the recipe for the lithography process and determining a value of a cost function based on the modeled outcome. The operation 706 can continue until a termination criterion is satisfied, as previously described in reference to the operation 406 of FIG. 4.

The operation 706 can comprise a source optimization operation, a mask optimization operation, or a combination thereof. The source optimization and the mask optimization can be performed concurrently, sequentially in either order, in series, in parallel, synchronously, asynchronously, etc. The source optimization and the mask optimization can be performed based on the same cost function. The source optimization and the mask optimization can have the same termination criterion. The source optimization can be performed by any appropriate method, such as those previously described in reference to the operation 408 of FIG. 4. The mask optimization can be performed by any appropriate method, such as those previously described in reference to the operation 410 of FIG. 4.

At an operation 708, performance metrics are determined for the lithography process. The performance metrics may be key performance metrics (KPI) or other performance metrics determined for the lithography process. The performance metrics may be determined based on modeling of the lithography process performed during or as a result of the SMO. The performance metrics may be determined based on measured metric for the lithography process, such as for a test wafer, for fabricated devices, etc. The performance metrics may be determined based on both modeling and measured metrics, based on modeling which is informed by measured metrics, etc. The performance metrics can include performance metric determined for previously fabricated device, such as for patterns and/or spectra which were previously used for a lithography process and which are to be included in training data. The performance metrics can include defect metrics, lithography metrics, process window conditions, etc. The performance metrics can include a cost-benefit analysis or another measure of the effect of the spectrum on device quality.

At an operation 710, it is determined if spectra remain to be selected for the lithography process. If spectra remain to be selected, flow continues to the operation 704 where an additional spectrum or spectra may be selected, generated, determined by adjustment of a previous spectra, etc. If spectra do not remain to be selected, flow continues to the operation 712. It may be determined that spectra do not remain to be selected based on iteration counts, remaining spectra of a set of spectra, time limitations, etc. It may be determined that spectra do not remain to be selected if a previous spectra is determined to be an optimal spectra or otherwise satisfy a criterion for optimization.

At an operation 712, it is determined if a layout and requirements remain to be obtained for a lithography process. If a layout and/or requirements remain to be selected, flow continues to the operation 702 where an additional layout and/or requirement may be selected. Multiple spectra for a layout and/or requirements may be analyzed and have performance metrics determined. The order in which the spectra are selected at the operation 704 need not be ordered based on layout and/or requirement identities, but may instead be selected in any appropriate order.

At an operation 714, training data is generated based on the performance metrics for the spectra and SMO for the layout and requirements of the lithography process. The training data may comprise labeled data, where the spectra, layout, and/or requirements are labeled by one or more performance metric. The training data may or may not include source optimization, mask optimization, or a combination thereof for a given spectra, layout, and/or requirements. The training data may be divided into one or more sets of training data, such as by pattern type and/or another pattern classification. The training data may include test data, validation data, etc. The training data may include spectra for which measured performance metrics are available, spectra for which modeled performance metrics are available, and spectra for which both measured and modeled performance metrics are available. The training data may include multiple performance metrics, including performance metrics which may or may not exhibit dependence on spectra. For example, a first performance metric may be affected by spectra for a design layout, while a second performance metric may be independent (or quasi-independent) of spectra for the design layout.

At an operation 716, a model is trained based on the training data. The model may be a mathematical model, such as a regression model. The model may be a machine learning model. The model may be an ensemble of machine learning models. The model may be a neural network, including a convolutional neural network (CNN). The model may be any appropriate machine learning model. The model may operate based on supervised learning. In some embodiments, the model may operate based on unsupervised learning. The model may be output to memory or otherwise stored. The model may be trained using any appropriate method. The model may be iteratively trained based on additional sets of training data. The model may be updated based on additional training data, including measured performance metrics for fabricated devices. The model may be trained for a specific lithography process, a type of lithography processes, etc. The model may be pre-trained based on a set of training data and further refined based on a more detailed or more specific set of training data.

As described above, method 700 (and/or the other methods and systems described herein) is configured to train a model for spectrum-aware optimization.

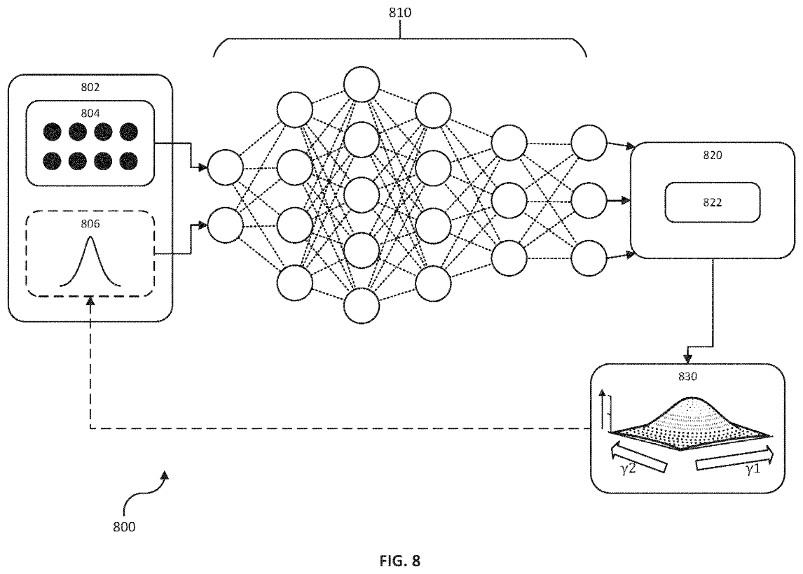

FIG. 8 is a schematic overview 800 of spectrum-aware optimization for a lithography process based on a trained model. A trained model 810 operates upon inputs 802 to determine outputs 820 for a lithography process. The trained model 810 can be trained in any appropriate manner, based on appropriate training data, such as that described in reference to FIG. 7. The inputs 802 to the trained model can comprise a pattern 804. The pattern 804 can comprise a design layout, a set of design requirements, a pattern type classification, etc. The pattern 804 can comprise a design layout for a whole wafer, a partial wafer, a set of features (or clips) or a wafer. The pattern 804 can include one or more pattern classification. The trained model 810 can include a pattern type identifier. The trained model 810 may also include multiple models, where the model applied to the pattern 804 may be determined based on the pattern type classification.

The inputs 802 may include a spectrum 806. The spectrum 806 may be a base spectrum—e.g., a spectrum that may be adjusted by the trained model 810 or based on the outputs 820 of the machine learning model. The spectrum 806 may include one or more components with one or more distributions as previously described. The spectrum 806 may be a spectrum previously determined for the lithography process or a similar lithography process. The spectrum 806 may be selected from a library of spectra. The spectrum 806 may be parameterized or may be input as a spectrum (e.g., in intensity versus wavelength form). The form of the spectrum 806 may depend on the form of the spectra which were used to train the trained model 810.

The outputs 820 of the trained model 810 may include one or more performance metrics 822. The outputs 820 of the trained model 810 may include a spectrum or an adjusted spectrum, such as an adjusted spectra based on the spectrum 806 of the inputs 802. The outputs 820 of the trained model 810 may include a set of spectra together with performance metrics 822 for the spectra of the set. The outputs 820 of the trained model 810 may include parameters of one or more spectra. The performance metrics may include predicted performance metrics 822. The performance metrics 822 may include interpolated performance metrics 822, such as performance metrics 822 based on one or more models. The performance metrics 822 may include confidence intervals, probabilities, distributions, etc. for one or more performance metrics 822. The outputs 820 may include indication of an adjustment to a spectrum or a spectrum for spectrum-aware optimization of the lithography process, where an adjusted spectrum may be generated from the spectrum 806 and the adjustment. The adjusted spectrum, with or without its corresponding performance metrics, may be used to updated or retrain the trained model 810. The outputs 820 may include information about a source optimization, mask optimization, or a combination thereof for the spectrum 806 of the inputs 802.

A performance metric parameter space 830 may be generated based on the performance metrics 822. The performance metric parameter space 830 may relate one or more performance metric to spectrum parameters. The performance metric parameter space 830 can be generated based on outputs 820 of the trained model 810 corresponding to multiple spectra 806. The performance metric parameter space 830 can be used to adjust spectra 806 iteratively to optimize one or more performance metrics 822 of the lithography process. The performance metric parameter space 830 can be updated based on additional inputs 802 and outputs 820 of the trained model 810.

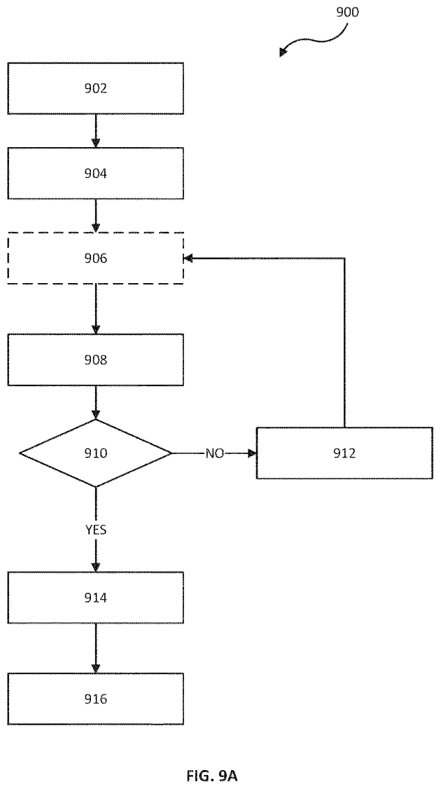

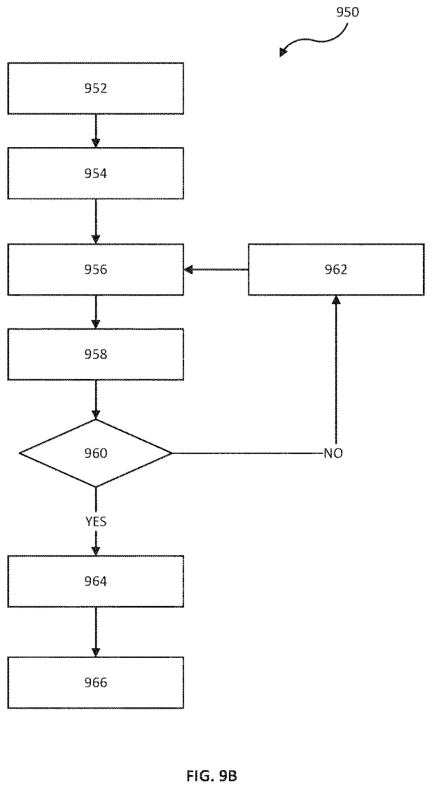

FIG. 9A illustrates an exemplary method 900 for spectrum adjustment using a model during spectrum-aware optimization for a lithography process. The operations of method 900 presented below are intended to be illustrative. In some embodiments, method 900 may be accomplished with one or more additional operations not described, and/or without one or more of the operations discussed. Additionally, the order in which the operations of method 900 are illustrated in FIG. 9A and described below is not intended to be limiting. In some embodiments, one or more portions of method 900 may be implemented (e.g., by simulation, modeling, etc.) in one or more processing devices (e.g., one or more processors). The one or more processing devices may include one or more devices executing some or all of the operations of method 900 in response to instructions stored electronically on an electronic storage medium. The one or more processing devices may include one or more devices configured through hardware, firmware, and/or software to be specifically designed for execution of one or more of the operations of method 900, for example.

At an operation 902, a layout and requirements are obtained for a lithography process. The layout and requirements may be obtained by any appropriate method, including those described in reference to the operation 702 of FIG. 7.

At an operation 904, a source-mask optimization (SMO) is performed for the lithography process. The SMO may be performed using any appropriate method, including the methods described in reference to the operation 706 of FIG. 7. The SMO may output a recipe for the lithography process.

At an operation 906, a spectrum is optionally selected for a radiation source of the lithography process. The spectrum may be selected using any appropriate method, including the methods described in reference to the operation 704 of FIG. 7.

At an operation 908, one or more performance metric is predicted based on the SMO for the lithography process and, optionally, the spectrum. The performance metric can be determined based on a model of the lithography process, such as an optical model, an etch model, a resist model, etc. The performance metric can be determined based on the selected spectrum. The performance metrics can be determined based on any appropriate method, such as those described in reference to the operation 708 of FIG. 7.

At an operation 910, it is determined if the performance metrics are acceptable. If the performance metrics are acceptable, flow continues to an operation 914, where the recipe corresponding to the SMO output can be checked against an LMC. If the performance metrics are not acceptable, flow continues to an operation 912, where the spectrum may be adjusted.

At the operation 912, the spectrum is adjusted based on a performance metric parameter space, such as the performance metric parameter space 830 described in relation to FIG. 8. The spectrum and/or a parameter of the spectrum can be correlated to one or more performance metrics based on a trained model, such as the trained model 810 of FIG. 8. Based on the correlation of spectra and/or parameters of spectra obtained from the trained model, as function which relates the one or more performance metric and a spectrum and/or parameter of a spectrum can be created. If the performance metrics of a current iteration of the recipe derived from the SMO and the selected spectra do not satisfy a performance metric (e.g., one or more of the performance metrics is determined to be unacceptable at the operation 910), then the spectrum and/or parameter of the spectrum can be adjusted in a direction based on the derived performance metric parameter space. In an example, the spectra can be parameterized based on a separation between components. A trained model can be used to generate a set of spectra with different values of the parameterization (for example, y). The model can determine (e.g., predict) values of one or more performance metric, such as EPE, based on the parameterization y. If the performance metric, such as EPE, for a current iteration of the spectrum does not satisfy an acceptable performance metric criterion, then the relationship between y and EPE determined based on the trained model can be used to determine in which direction and/or in which magnitude to adjust y. This example is provided for illustration only. The adjustment of the spectrum can comprise adjustment in multiple directions, including multi-variable adjustment.

At the operation 914, the recipe obtained from the SMO and based on the spectrum is checked for lithography compatibility. The recipe may be checked for lithography compatibility using any appropriate method, including the methods described in reference to the operation 418 of FIG. 4.

At the operation 916, the recipe is output. The recipe may be output and/or stored using any appropriate methods, such as those described in reference to the operation 420 of FIG. 4.

As described above, method 900 (and/or the other methods and systems described herein) is configured to adjust a spectrum using a model during spectrum-aware optimization for a lithography process.

FIG. 9B illustrates an exemplary method 950 for spectrum determination using a model during spectrum-aware optimization for a lithography process, according to an embodiment. The operations of method 950 presented below are intended to be illustrative. In some embodiments, method 950 may be accomplished with one or more additional operations not described, and/or without one or more of the operations discussed. Additionally, the order in which the operations of method 950 are illustrated in FIG. 9B and described below is not intended to be limiting. In some embodiments, one or more portions of method 950 may be implemented (e.g., by simulation, modeling, etc.) in one or more processing devices (e.g., one or more processors). The one or more processing devices may include one or more devices executing some or all of the operations of method 950 in response to instructions stored electronically on an electronic storage medium. The one or more processing devices may include one or more devices configured through hardware, firmware, and/or software to be specifically designed for execution of one or more of the operations of method 950, for example.

At an operation 952, a layout and requirements are obtained for a lithography process. The layout and requirements may be obtained by any appropriate method, including those described in reference to the operation 902 of FIG. 9A.

At an operation 954, a source-mask optimization (SMO) is performed for the lithography process. The SMO may be performed using any appropriate method, including the methods described in reference to the operation 906 of FIG. 9A. The SMO may output a recipe for the lithography process.

At an operation 956, an optimal spectrum is determined based on a trained model. The optimal spectrum is determined based on the recipe determined during the SMO. The optimal spectrum is determined based on inputting the recipe of the lithography process into the trained model, where the trained model is trained to identify a spectrum based on a design layout, set of requirements, and/or recipe of the lithography process. The optimal spectrum is not required to be the absolute optimal spectrum, but rather a spectrum which is at least better in some respects that other spectrum.

At an operation 958, one or more performance metric is predicted based on the SMO for the lithography process and, optionally, the spectrum. The performance metrics can be determined based on any appropriate method, such as those described in reference to the operation 908 of FIG. 9A.

At an operation 960, it is determined if the performance metrics are acceptable. If the performance metrics are acceptable, flow continues to an operation 964, where the recipe corresponding to the SMO output can be checked against an LMC. If the performance metrics are not acceptable, flow continues to an operation 962, where the spectrum may be adjusted.

At the operation 962, at least one of the spectrum, the source optimization, the mask optimization, or a combination thereof is adjusted is the spectrum does not correspond to acceptable performance metrics. The adjustment can be selected from a set of operations for adjustment. The adjustment can include re-optimization. The adjustment can comprise selection of a secondary spectrum based on the trained model. The adjustment can comprise selecting an adjustment direction and/or magnitude based on a performance metric parameter space, such as previously described in relation to the operation 912 of FIG. 9A. The adjustment can comprise determining that a different model should be used, and selecting a spectrum based on output of the different model.

At the operation 964, the recipe obtained from the SMO and based on the spectrum is checked for lithography compatibility. The recipe may be checked for lithography compatibility using any appropriate method, including the methods described in reference to the operation 914 of FIG. 9A.

At the operation 966, the recipe is output. The recipe may be output and/or stored using any appropriate methods, such as those described in reference to the operation 916 of FIG. 9A.

As described above, method 900 (and/or the other methods and systems described herein) is configured to adjust a spectrum using a model during spectrum-aware optimization for a lithography process.

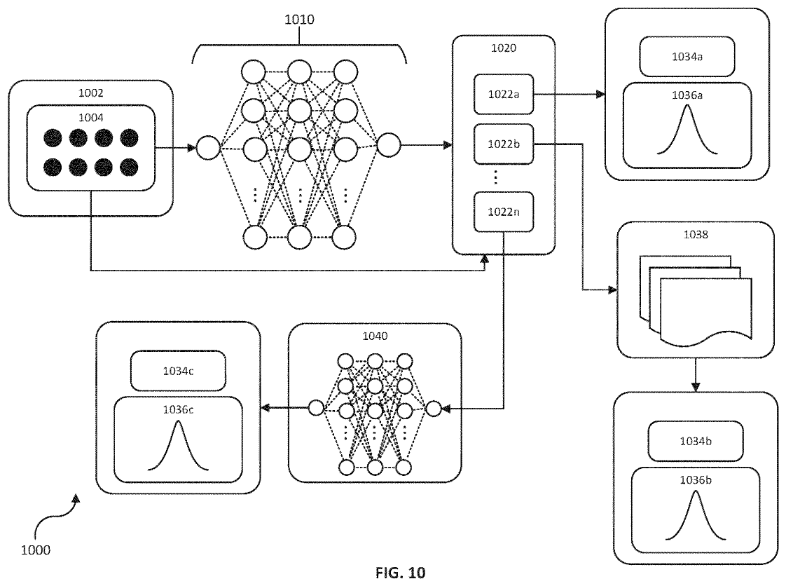

FIG. 10 is a schematic overview 1000 of spectrum-aware optimization with pattern classification. A trained model 1010 operates upon inputs 1002 to classify patterns 1004 for a lithography process. The trained model 1010 can be trained in any appropriate manner to classify patterns based on any appropriate classifications. The trained model 1010 can operate based on unsupervised learning, where the trained model 1010 can identify classes. The trained model 1010 can also operate based on supervised learning, where classes can be identified in training data. The trained model 1010 can classify patterns into one or more classification output 1020. The trained model 1010 can determine a classification confidence for the patterns 1004 of the inputs 1002. The trained model 1010 can classify the patterns 1004 of the inputs 1002 using multi-class classification. The patterns 1004 can be identified as corresponding to two or more classes, in a union of classes, an intersection of classes, etc. In a non-limiting illustrative example, the patterns 1004 of the inputs 1002 can be classified as corresponding to one or more of the classes 1022a-1022n.

For each of the classes of the classification output 1020, one or more process for spectrum-aware optimization can be performed. In the non-limiting, illustrative example, patterns 1004 identified as corresponding to the class 1022a can be directly associated with spectra 1036a and performance metrics 1034a. The patterns 1004 of the class 1022a can be associated with spectra 1036a based on a brute force method, for which multiple spectra 1036a are optimized and performance metrics 1034a determined. The patterns 1004 of the class 1022a can be patterns for which an optimal spectra is known, based on previous experience or modeling. For example, the patterns 1004 of the class 1022a can be patterns for which a single peak spectrum with a minimal FWHM is the optimal spectrum. The wavelengths of the spectrum may or may not be variable. In the example, the performance metrics 1034a can be determined for each pattern 1004 of the class 1022a, or may be determined for the patterns 1004 of the class 1022a as a class.

In the non-limiting, illustrative example, patterns 1004 identified as corresponding to the class 1022b can be associated with one or more spectra of a spectral library 1038. The spectral library 1038 may comprise spectra for which performance metrics have been precalculated. The spectral library 1038 may comprise spectra associated with one or more patterns 1004 for which performance metrics have been calculated. A spectrum 1036b can be selected from the spectral library 1038 based on the pattern of the spectral library which each of the patterns corresponding to the class 1022b most closely resemble. More than one spectrum can be selected from the spectral library 1038, and a spectrum 1036b can be determined based on a composition, interpolation, average, etc. of the selected spectra. The spectrum 1036b can be selected from the spectral library 1038 based on performance metrics associated with the spectra of the spectral library. The spectrum 1036b can performance metrics 1034b, which are selected from the spectral library with the spectrum 1036b.

In the non-limiting, illustrative example, patterns 1004 identified as corresponding to the class 1022n can be associated with one or more spectra based on a trained model 1040. The trained model may output a spectrum 1036c and performance metrics 1034c based on any appropriate method, such as those described in reference to FIGS. 9A and 9B.

For patterns 1004 identified as corresponding to more than one class, optimal spectrums can be determined based methods associated with one or more of the classes to which the patterns 1004 are identified as belonging. For example, a spectrum can be determined by a first method and a second method, where an optimal spectrum can be determined based on the first method, the second method, or a combination thereof. The optimal spectrum can be selected based on which method corresponds to better performance metrics. The optimal spectrum can be selected based on a combination of spectra produces by various methods. The optimal spectrum can be selected based on a confidence interval or probability for the one or more spectra.

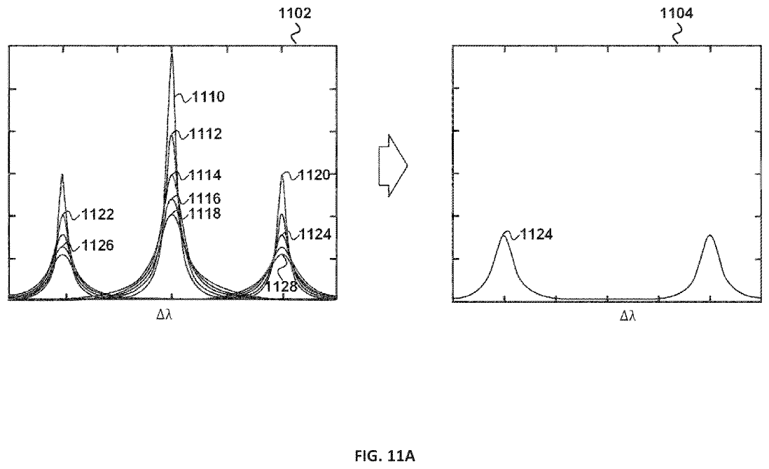

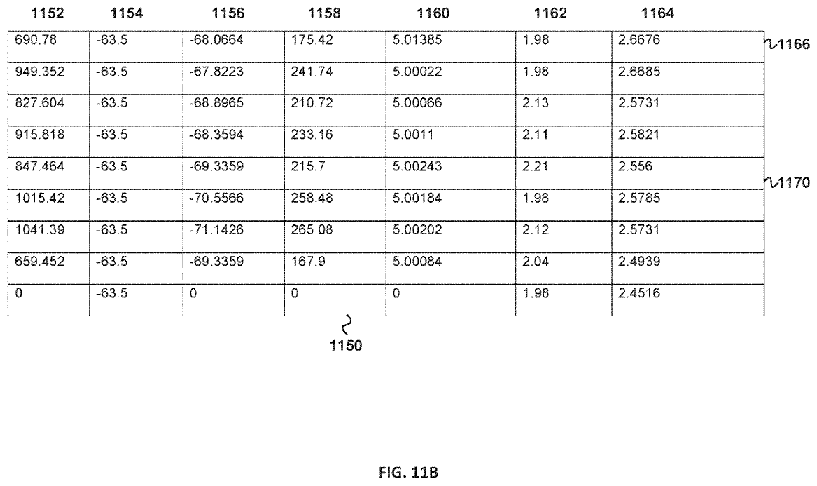

FIG. 11A depicts example spectra for spectrum-aware optimization for an example lithography process. FIG. 11A depicts an example graph 1102 depicting a set of spectra for the example lithography process. The example graph 1102 depicts both spectra with single peaks (e.g., single components), such as spectra 1110, 1112, 1114, 1116, and 1118, and spectra with double peaks (e.g., dual components), such as spectra 1120, 1122, 1124, 1126, and 1128. The example graph depicts spectra with a variety of peak distributions, including higher and lower FWHM. For example, the spectrum 1110 has a smaller FWHM that the spectrum 1118 with which it is co-located. The example graph 1104 depicts an optimal spectrum of the set of spectra of the graph 1102 of the example lithography process. Based on performance metrics, the spectrum 1124 is the optimal spectrum for the lithography process. The spectrum 1124 is both a dual component spectrum and, further, not the dual component spectrum with the smallest FWHM. Small FWHM is traditionally thought to be correlated with optimal spectrum, but for spectrum-aware optimization of a lithography process this may not be the case. The spectrum 1124 is also not the dual component with the largest FWHM, which suggests that the relationship between performance metrics and FWHM may be more complex than previously understood.

FIG. 11B depicts graphs showing process window improvement due to spectrum-aware optimization for the example lithography process of FIG. 11A. FIG. 11B depicts a chart 1150 which displays performance metrics for the spectra of FIG. 11A. The performance metrics, exposure window area 1152, nominal focus 1154, focus center 1156, depth of focus 1158, exposure latitude 1160, MEEF 1162, and NIFS at DoF 1164, are displayed for the spectra of FIG. 11A. The first row of the chart, row 1166, corresponds to the spectra 1110 of FIG. 11A. Row 1170 corresponds to the spectrum 1124 of FIG. 11A, the optimal spectrum. As depicted in the chart 1150, the performance metrics of the spectrum 1124 display in excess of a 50% enhancement in nDOF relative to the spectra 1110 of FIG. 11A, taken as baseline.

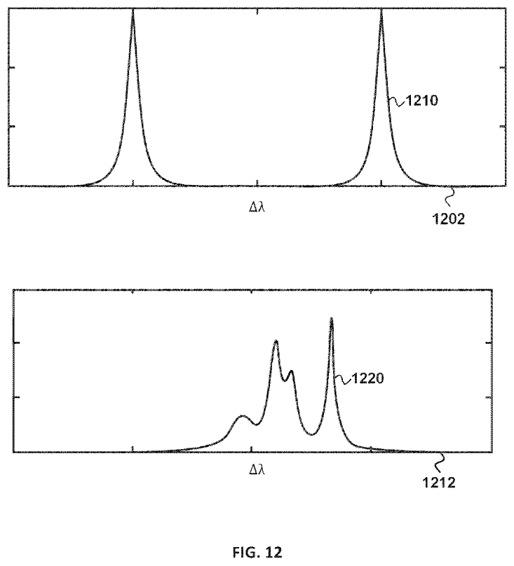

FIG. 12 depicts example spectra determined by spectrum-aware optimization for an example lithography process. FIG. 12 depicts a chart 1202 comprising spectra 1210. Spectrum 1210 is composed of two components. FIG. 12 also depicts a chart 1212, comprising spectrum 1220. Spectrum 1220 is composed of numerous components. The spectra 1220 can be a freeform spectra, where a freeform spectra may be comprised of numerous components. A freeform spectra can also correspond to a spectra for which an intensity is determined for substantially all wavelength and which is then composed from components available from a radiation source. The freeform spectra can be a digital waveform, such as a sawtooth, sinusoid, etc. or other distributions of wavelengths not commonly produced by radiative excitation. The spectrum 1210 and the spectrum 1220 can be generated by a single radiation source or by multiple radiation sources. A radiation source can generate one or more excitations, such as laser excitations, from a material via optoelectronic circuitry. The radiation source can include optical circuitry which can alter a wavelength, distribution, intensity, etc. of a component produced by the radiation source. The radiation source can include optical circuitry which can split a component into parts, which can each be altered separately. The radiation source can generate multiple peaks from a single component or can combine multiple components from separate excitations or sources. The radiation source can include filters, beam splitters, diffraction elements, etc. which alter optical characteristics of one or more components of the spectrum.

The embodiments may further be described using the following clauses:
1. A method, comprising:
   acquiring, by a computer system, a plurality of design variables that represent at least one of characteristics of a lithographic process, geometrical characteristics of a design layout, or a combination thereof; and
   determining, by the computer system, a spectrum for a radiation source of a lithographic apparatus based on at least one of the plurality of design variables, the characteristics of the lithographic process, the geometrical characteristics of the design layout, or a combination thereof.
2. The method of clause 1, wherein the determining comprises determining, by the computer system, one or more parameters of the spectrum for the radiation source.
3. The method of clause 2, wherein the one or more parameters of the spectrum for the radiation source comprise at least one of a number of components, a wavelength separation between two or more components, a frequency separation between two or more components, a component shape, a component distribution, a component intensity, a relative intensity of two components, a component nominal focus, a component focus center, a component displacement, or a combination thereof.
4. The method of clause 1, wherein the determining comprises:
   determining, by the computer system, the spectrum for the radiation source based on a latitude of at least one of the plurality of design variables.
5. The method of clause 4, wherein the latitude comprises latitude for at least one of depth of focus, exposure, common process window, image contrast, image log slope (ILS), normalized image log slope (NILS), or a combination thereof.
6. The method of clause 1, wherein the determining comprises:
   determining, by the computer system, the spectrum for the radiation source based on a at least one lithographic metric.
7. The method of clause 6, wherein the at least one lithographic metric comprises at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), an image contrast, an image contrast latitude, a usable process window above a specific NILS threshold (nDOF), or a combination thereof.
8. The method of clause 1, wherein the determining comprises:
   determining, by the computer system, a spectrum for the radiation source from a plurality of spectra based on at least one of a lithographic metric, a design variable latitude, or a combination thereof,
wherein the plurality of spectra comprise spectra for which at least one value of a lithographic metric, a design variable latitude, or a combination thereof has been pre-computed.
9. The method of clause 8, wherein the determining comprises:
   selecting, by the computer system, multiple spectra from the plurality of spectra; and determining a spectrum for the radiation source based on a combination of the multiple spectra.
10. The method of clause 1, wherein the determining comprises:
   determining, by the computer system, a spectrum for the radiation source based on a machine learning model trained to determine an optimal spectrum from at least one of the plurality of design variables, the characteristics of the lithographic process, the geometrical characteristics of the design layout, or a combination thereof.
11. The method of clause 10, wherein the machine learning model is trained to determine an optimal spectrum based on at least one lithographic metric.
12. The method of clause 10, wherein the machine learning model is further trained to generate an optimal spectrum based on a combination of multiple contributing components.
13. The method of clause 12, wherein the combination comprises a linear combination.
14. The method of clause 12, wherein the combination comprises a convolution of at least two of the multiple contributing components.
15. The method of clause 12, wherein the combination comprises an interpolation.
16. The method of clause 12, wherein at least one of the multiple contributing components is a Lorentzian.
17. The method of clause 12, wherein at least one of the multiple contributing components is a Gaussian.
18. The method of clause 12, wherein at least one of the multiple contributing components comprises a Voigt profile.
19. The method of clause 10, wherein the optimal spectrum is a freeform spectrum.
20. The method of clause 10, wherein the optimal spectrum has at least one of a smooth profile, a discontinuous profile, a non-differentiable profile, or a piece-wise combination thereof.
21. A method, comprising:
   acquiring a plurality of target patterns;
   acquiring a plurality of design variables that represent characteristics of lithographic processes for the plurality of target patterns;
   acquiring a plurality of spectra for a radiation source for the lithographic processes;
   determining lithographic metrics for the plurality of spectra for the plurality of target patterns based on the plurality of design variables that represent characteristics of the lithographic processes for the plurality of target patterns; and
   training a model, by using the lithographic metrics for the plurality of spectra, to determine one or more optimal spectra for a lithographic process based on an input target pattern, a set of design variables that represent characteristics of the lithographic process for the input target pattern, or a combination thereof.
22. A method, comprising:
   acquiring a plurality of target patterns;
   acquiring a plurality of laser spectra for a radiation source for a lithographic process;
   generating a set of training data comprising lithographic metrics by computing source-mask optimizations for the lithographic process for the plurality of target patterns and the plurality of laser spectra; and
   training, by a computing system, a model using the set of training data to determine one or more optimal laser spectra for the lithographic process, wherein the model is a machine learning model.
23. The method of clause 21, wherein the model comprises a machine learning model.
24. The method of any one of clauses 22 or 23, wherein the machine learning model comprises a neural network.
25. The method of any one of clauses 22 or 23, wherein the machine learning model comprises a convolutional neural network.
26. The method of any one of clauses 21 or 22, wherein the model comprises a regression model.
27. The method of any one of clauses 21 or 22, wherein the model comprises an ensemble of machine learning models.
28. The method of any one of clauses 21 or 22, wherein the training comprises:
   training the model to determine an optimal spectrum.
29. The method of clause 28, wherein the training comprises:
   training the model to determine an optimal spectrum based on a combination of the one or more optimal spectra.
30. The method of any one of clauses 21 or 22, wherein the lithographic metrics comprises at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination thereof.
31. The method of any one of clauses 21 or 22, wherein the training the model to determine one or more optimal spectra for the lithographic process comprises training the model to determine one or more optimal parameter of a spectrum for the lithographic process.
32. The method of clause 31, wherein the one or more optimal parameter comprises comprise at least one of a number of components, a wavelength separation between two or more components, a frequency separation between two or more components, a component shape, a component distribution, a component intensity, a relative intensity of two components, a component nominal focus, a component focus center, a component displacement, or a combination thereof.
33. The method of any one of clauses 21 or 22, wherein lithographic metrics comprise performance indicators.
34. The method of clause 21, further comprising:
   acquiring a production target pattern, a set of design variables for that represent characteristics of the lithographic process for the production target pattern, of a combination thereof; and
   determining one or more optimal spectra for the lithographic process for the production target pattern based on the trained model.
35. The method of clause 22, further comprising:
   acquiring a production target pattern; and
   determining one or more optimal spectra for the lithographic process for the production target pattern based on the trained model.
36. The method of any one of clauses 21 or 22, wherein the training comprises training the model to determine one or more optimal spectra based on an input target pattern type.
37. The method of clause 36, wherein the training comprises training the model to determine an input target pattern type.
38. A method, comprising:
   computing, by a computer system, a multi-variable cost function of a plurality of design variables that represent characteristics of a lithographic process, the multi-variable cost function being a function of a spectrum of a radiation source of a lithographic apparatus, or being a function of a variable that is a function of the spectrum or that affects the spectrum; and
   reconfiguring, by the computer system, one or more of the characteristics of the lithographic process by adjusting one or more of the plurality of design variables until a termination criteria is satisfied.
39. A method comprising:
   computing, by a computer system, a multi-variable cost function being a function of a plurality of design variables that represent characteristics of a lithographic process; and reconfiguring, by the computer system, one or more of the characteristics of the lithographic process by adjusting one or more of the plurality of design variables and re-computing the multi-variable cost function based on the adjusted one or more of the plurality of design variables until a certain termination condition is satisfied, wherein a spectrum of a radiation source of a lithographic apparatus is adjustable during the reconfiguring.
40. The method of clause 38 or 39, wherein the reconfiguring is under a constraint that geometrical characteristics of a patterning device comprising a design layout of the lithographic process are substantially unchanged.
41. The method of clause 38 or 39, wherein the reconfiguring comprises adjusting the spectrum of the radiation source.
42. The method of clause 38 or 39, wherein the reconfiguring comprises selecting the spectrum of the radiation source from a plurality of spectra of the radiation source.
43. The method of clause 38 or 39, wherein the spectrum of the radiation source is comprised of multiple contributing components.
44. The method of clause 43, wherein the spectrum is comprised of a combination of contributing components.
45. The method of clause 43, wherein at least one of the multiple contributing components is a Lorentzian.
46. The method of clause 43, wherein at least one of the multiple contributing components is a Gaussian.
47. The method of clause 43, wherein at least one of the multiple contributing components comprise a Voigt profile.
48. The method of clause 38 or 39, wherein the spectrum of the radiation source has at least one of a smooth profile, a discontinuous profile, a non-differentiable profile, or a piece-wise combination thereof.
49. The method of clause 38 or 39, wherein the reconfiguring improves an image quality characteristic of the lithographic process.
50. The method of clause 38 or 39, wherein the reconfiguring increases a latitude of at least one of the plurality of design variables.
51. The method of clause 50, wherein the latitude comprises a latitude for at least one of depth of focus, exposure, common process window, image contrast, image log slope (ILS), normalized image log slope (NILS), or a combination thereof.
52. The method of clause 38 or 39, wherein the multi-variable cost function evaluates at least one of an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination thereof.
53. The method of clause 38 or 39, wherein the reconfiguring comprises an optimization of the multi-variable cost function.
54. The method of clause 38 or 39, wherein the reconfiguring comprises a gradient-based optimization.
55. One of more non-transitory, machine-readable medium having instructions thereon, the instructions when executed by a processor being configured to perform the method of any one of clauses 1 to 54.
56. A system comprising:
   a processor; and
   one or more non-transitory, machine-readable medium having instructions thereon, the instructions when executed by the processor being configured to perform the method of any one of clauses 1 to 54.
57. A system comprising:
   a radiation source;
   a processor, operatively connected to control a spectrum of the radiation source; and
   one or more non-transitory, machine-readable medium having instructions thereon, the instructions when executed by the processor being configured to:
      acquire a plurality of design variables that represent at least one of characteristics of a lithographic process, geometrical characteristics of a design layout, or a combination thereof;
      determine a spectrum for the radiation source based on at least one of the plurality of design variables, the characteristics of the lithographic process, the geometrical characteristics of the design layout, or a combination thereof; and
      control the radiation source to emit the spectrum during a lithographic process.
58. The system of clause 57, wherein the radiation source comprises a laser.
59. The system of clause 57, wherein the radiation source comprises multiple sources of radiation.
60. The system of clause 59, further comprising a multiplexer, wherein the multiplexer combines outputs of the multiple sources of radiation to generate the spectrum.
61. The system of clause 57, wherein instructions to control the radiation source further comprise instruction to control a wavelength distribution of a component of the spectrum.

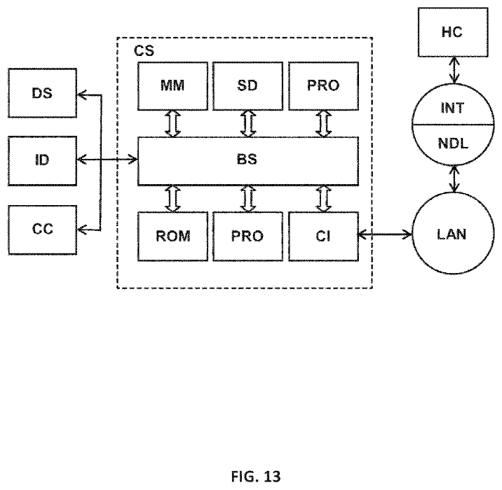

FIG. 13 is a block diagram of an example computer system CS, according to an embodiment. Computer system CS may assist in implementing the methods, flows, or the apparatus disclosed herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO, for example. Computer system CS includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

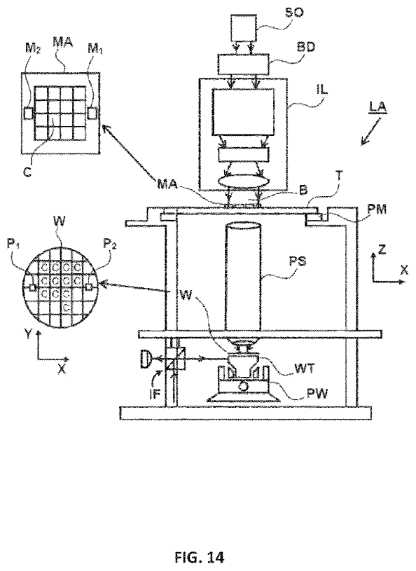

FIG. 14 is a schematic diagram of a lithographic projection apparatus, according to one or more embodiments. The lithographic projection apparatus can include an illumination system IL, a first object table MT, a second object table WT, and a projection system PS.

Illumination system IL can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner PM to accurately position the patterning device with respect to item PS.

Second object table (substrate table) WT can be provided with a substrate holder to hold a substrate W (e.g., a resist-coated silicon wafer), and connected to a second positioner PW to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into illumination system (illuminator) IL, either directly or after having traversed conditioning apparatuses, such as a beam expander, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario may be the case when source SO is an excimer laser (e.g., based on KrF, ArF or F2 lasing).

The beam B can subsequently intercept patterning device MA, which is held on a patterning device table MT. Having traversed patterning device MA, the beam B can pass through the lens, which focuses beam B onto target portion C of substrate W. With the aid of the second positioning apparatus (and interferometric measuring apparatus IF), the substrate table WT can be moved accurately, e.g., so as to position different target portions C in the path of beam B. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam B.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

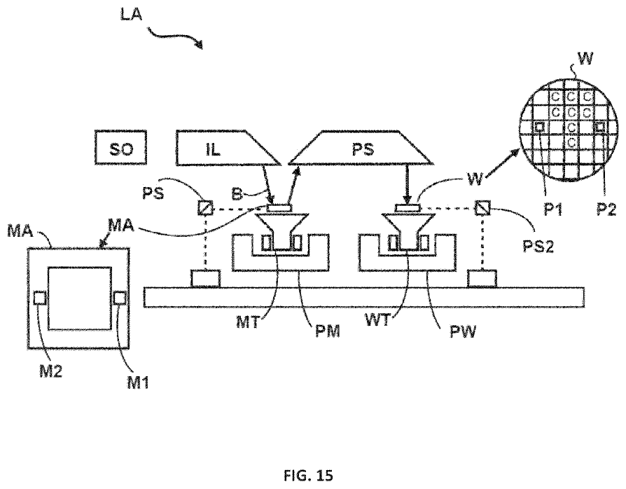

FIG. 15 is a schematic diagram of another lithographic projection apparatus (LPA), according to one or more embodiments. LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g. a mask or a reticle) MA and connected to a first positioner PM configured to accurately position the patterning device.

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e., a single dynamic exposure). The velocity and direction of substrate table WT relative to the support structure (e.g., patterning device table) MT may be determined by the (de-) magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

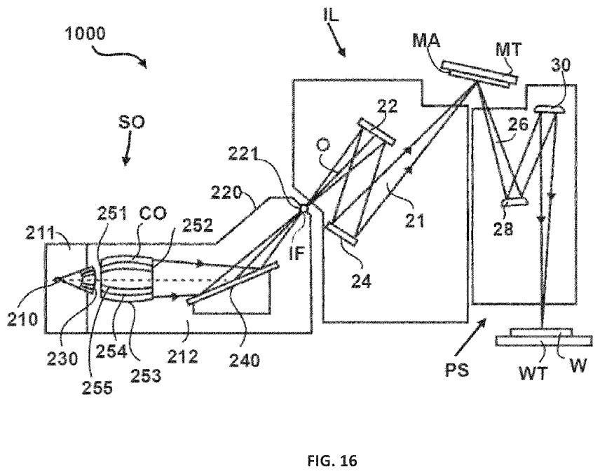

FIG. 16 is a detailed view of the lithographic projection apparatus, according to one or more embodiments. As shown, LPA can include the source collector module SO, the illumination system IL, and the projection system PS. The source collector module SO is configured such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

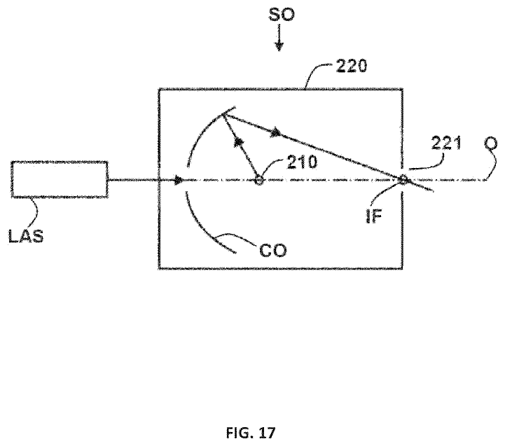

FIG. 17 is a detailed view of source collector module SO of lithographic projection apparatus LPA, according to one or more embodiments. Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments. For example, adding single or multiple assist features as described herein may comprise their own separate embodiments, or they may be included with one or more other embodiments described herein.

The descriptions above are intended to be illustrative, not limiting. Thus, it will be apparent to one skilled in the art that modifications may be made as described without departing from the scope of the claims set out below.

1. A method, comprising:
generating a set of training data comprising lithographic metrics by computing source-mask optimizations for a lithographic process for a plurality of target patterns and a plurality of laser spectra for a radiation source for the lithographic process; and
training, by a hardware computing system, a model using the set of training data to determine one or more optimal laser spectra for the lithographic process, wherein the model is a machine learning model.

2. The method of claim 1, wherein the machine learning model comprises a neural network.

3. The method of claim 1, wherein the machine learning model comprises a convolutional neural network.

4. The method of claim 1, wherein the model comprises a regression model.

5. The method of claim 1, wherein the model comprises an ensemble of machine learning models.

6. The method of claim 1, wherein the training comprises training the model to determine an optimal spectrum.

7. The method of claim 6, wherein the training comprises training the model to determine an optimal spectrum based on a combination of the one or more optimal spectra.

8. The method of claim 1, wherein the lithographic metrics comprises at least one selected from: an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination selected therefrom.

9. The method of claim 1, wherein the training the model to determine one or more optimal spectra for the lithographic process comprises training the model to determine one or more optimal parameters of a spectrum for the lithographic process.

10. The method of claim 9, wherein the one or more optimal parameters comprises at least one selected from: a number of spectrum components, a wavelength separation between two or more spectrum components, a frequency separation between two or more spectrum components, a spectrum component shape, a spectrum component distribution, a spectrum component intensity, a relative intensity of two spectrum components, a spectrum component nominal focus, a spectrum component focus center, a spectrum component displacement, or a combination selected therefrom.

11. The method of claim 1, wherein the lithographic metrics comprise one or more performance indicators.

12. The method of claim 1, further comprising:
acquiring a production target pattern; and
determining one or more optimal spectra for the lithographic process for the production target pattern based on the trained model.

13. The method of claim 1, wherein the training comprises training the model to determine one or more optimal spectra based on an input target pattern type.

14. The method of claim 13, wherein the training comprises training the model to determine an input target pattern type.

15. One of more non-transitory, machine-readable medium having instructions therein, the instructions, when executed by one or more processors, configured to cause the one or more processors to perform at least the method of claim 1.

16. A method, comprising:
acquiring a plurality of design variables that represent characteristics of lithographic processes for a plurality of target patterns;
acquiring a plurality of spectra for a radiation source for the lithographic processes;
determining lithographic metrics for the plurality of spectra based on the plurality of design variables; and
training a model, by a hardware computing system and by using the lithographic metrics for the plurality of spectra, to determine one or more optimal spectra for a lithographic process based on an input target pattern and/or a set of design variables that represent characteristics of the lithographic process for the input target pattern.

17. The method of claim 16, wherein the model comprises an ensemble of machine learning models.

18. The method of claim 16, wherein the training comprises training the model to determine an optimal spectrum based on a combination of the one or more optimal spectra.

19. The method of claim 16, wherein the lithographic metrics comprises at least one selected from: an edge placement error (EPE), a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, an image shift, a mask error enhancement factor, a focus, a depth of focus (DOF), a DOF latitude, a critical dimension depth of focus, a process window latitude, a common process window latitude, an image log slope (ILS), a normalized image log-slope (NILS), a usable process window above a specific NILS threshold (nDOF), or a combination selected therefrom.

20. One of more non-transitory, machine-readable medium having instructions therein, the instructions, when executed by one or more processors, configured to cause the one or more processors to perform at least the method of claim 16.
